(19) United States
(12) Patent Application Publication
(10) Pub. No.: US 2013/0062688 A1
(43) Pub. Date: Mar. 14, 2013

(54) SEMICONDUCTOR DEVICE AND METHOD FOR MANUFACTURING SAME

(71) Applicant: Hitoshi KOBAYASHI, Kanagawa-ken (JP)

(72) Inventor: Hitoshi KOBAYASHI, Kanagawa-ken (JP)

(73) Assignee: Kabushiki Kaisha Toshiba, Tokyo (JP)

(21) Appl. No.: 13/420,550

(22) Filed: Mar. 14, 2012

(30) Foreign Application Priority Data
Sep. 13, 2011 (JP) 2011-199238

(51) Int. Cl. H01L 29/78; H01L 21/425

(52) U.S. Cl. 257/330; 438/530; 257/E29.262; 257/E21.473

(57) ABSTRACT

According to an embodiment, a semiconductor device includes a semiconductor layer, a first semiconductor region provided on the semiconductor layer, a second semiconductor region, a first control electrode and a second control electrode. The first control electrode faces the first and second semiconductor regions through an insulating film in a trench, the trench piercing through the first semiconductor region, the trench having a bottom face at a position deeper than the first semiconductor region. The second control electrode extends to the bottom face of the trench and has a portion between the bottom face and the first control electrode. The semiconductor layer includes a first portion between an end of the first semiconductor region and an end of the second control electrode, a first conductive type carrier concentration in the first portion being lower than a first conductive type carrier concentration in other portions in the semiconductor layer.

### CROSS-REFERENCE TO RELATED APPLICATIONS

This application is based upon and claims the benefit of priority from Japanese Patent Application No. 2011-199238, filed on Sep. 13, 2011; the entire contents of which are incorporated herein by reference.

### FIELD

Embodiments are related generally to a semiconductor device and a method for manufacturing the same.

### BACKGROUND

There are demands for sustaining higher voltage and reducing ON resistance to suppress a power loss in semiconductor devices used in the power control field. On the other hand, when seeking for the higher breakdown voltage and the lower ON resistance, a conflict occurs in a material property and raises a tradeoff in the device design.

For example, even in power MOSFETs used in a voltage range from 60 to 250 V, a resistance of a drift layer has a dominant influence over a drain-source voltage V_{dss} and an ON resistance R_{onA}. Using an epitaxial layer at a low concentration for the drift layer increases the breakdown voltage, and also increases the ON resistance. Thus, a novel structure has been investigated, which implements a high breakdown voltage and a low ON resistance at the same time. However, such a structure becomes complicated, and manufacturing costs thereof tend to increase. Hence, there is a need for the semiconductor device that can be easily manufactured and implement both demands for the higher breakdown voltage and the lower ON resistance.

### BRIEF DESCRIPTION OF THE DRAWINGS

FIG. 1 is a cross-sectional view schematically illustrating a semiconductor device according to a first embodiment;

FIGS. 2A and 2B are graphs illustrating a carrier concentration distribution and an electric field distribution of the semiconductor device according to the first embodiment;

FIGS. 3A and 3B are graphs illustrating a carrier concentration distribution and an electric field distribution of a semiconductor device according to a comparative example;

FIGS. 4A and 4B are graphs illustrating a carrier concentration distribution and an electric field distribution of a semiconductor device according to another comparative example;

FIGS. 5A to 9B are schematic cross-sectional views illustrating a manufacturing process of the semiconductor device according to the first embodiment;

FIG. 10 is a cross-sectional view schematically illustrating a semiconductor device according to a second embodiment;

FIGS. 11A and 11B are schematic cross-sectional views illustrating a manufacturing process of the semiconductor device according to the second embodiment;

FIG. 12 is a cross-sectional view schematically illustrating a semiconductor device according to a third embodiment;

FIGS. 13A and 13B are graphs illustrating a carrier concentration distribution and an electric field distribution of the semiconductor device according to the third embodiment; and

FIG. 14 is a cross-sectional view schematically illustrating a semiconductor device according to a variation of the third embodiment.

### DETAILED DESCRIPTION

According to an embodiment, a semiconductor device includes a semiconductor layer of a first conductive type, a first semiconductor region of a second conductive type provided on the semiconductor layer, a second semiconductor region of a first conductive type selectively provided on a surface of the first semiconductor region, and a first control electrode facing the first semiconductor region and the second semiconductor region through an insulating film in a trench. The trench pierces through the first semiconductor region and reaches the semiconductor layer, the trench having a bottom face at a position deeper than the first semiconductor region. The semiconductor device also includes a second control electrode extending to the bottom face of the trench and having a portion located between the bottom face and the first control electrode, a first major electrode electrically connected to the first semiconductor region and the second semiconductor region, and a second major electrode electrically connected to the semiconductor layer,

Embodiments will now be described with reference to the drawings. Identical components in the drawing are marked with the same reference numerals, and a detailed description thereof is omitted as appropriate and different components will be described. In the embodiments below, an explanation will be given using an example in which a first conductive type is an n-type and a second conductive type is a p-type. However, the types are not limited to this explanation. The first conductive type may be a p-type, and the second conductive type may be an n-type.

### First Embodiment

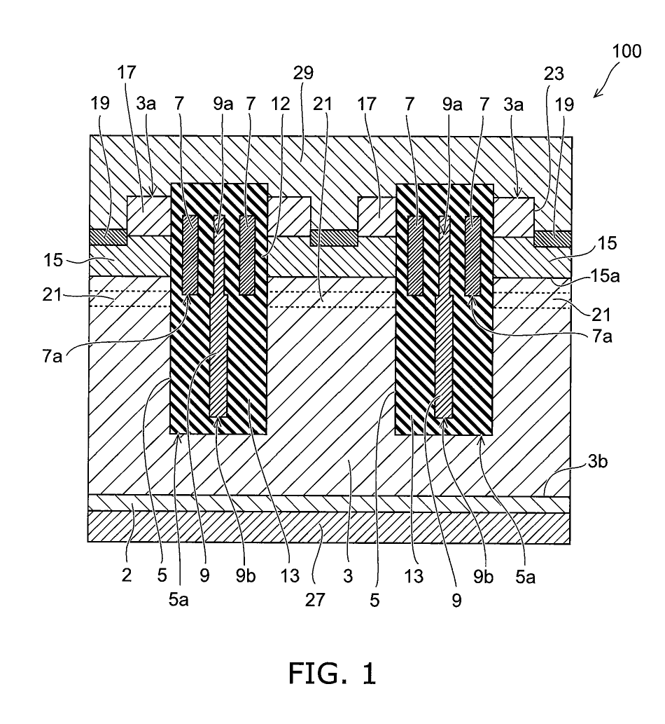

FIG. 1 is a cross-sectional view schematically illustrating a semiconductor device 100 according to a first embodiment. As shown in FIG. 1, the semiconductor device 100 is a trench gate power MOSFET (Metal Oxide Semiconductor Field Effect Transistor) having a field plate electrode (an FP electrode) 9.

The semiconductor device 100 includes an n-type drift layer 3 (a semiconductor layer of a first conductive type) provided on an n⁺ drain layer 2, a p-type base region 15 (a first semiconductor region) provided on the n-type drift layer 3, and an n-type source region 17 (a second semiconductor region) selectively provided on the surface of the p-type base region 15.

The semiconductor device 100 has a trench 5 piercing through the p-type base region 15 from a first major surface 3a and reaching the n-type drift layer 3. A bottom face 5a of the trench 5 is located between the second major surface 3b and the p-type base region 15. In the trench 5, two gate electrodes 7 (first control electrodes) are provided, facing the p-type base region 15 and the n-type source region 17 through a gate insulating film 12.

As described later, the p-type base region 15 and the n-type source region 17 are provided on the first major surface 3a of the n-type drift layer 3. Therefore, in the structure of the completed device shown in FIG. 1, the first major surface 3a of the n-type drift layer 3 is the surface of the n-type source region 17. For convenience, portions except the p-type base region 15 and the n-type source region 17 of the n-type drift layer 3 are sometimes simply referred to as the n-type drift layer 3. In the case where the depth position is referred in the following explanation, the depth position means positional relationship in a direction from the first major surface 3a toward a second major surface 3b.

In the trench 5, the FP electrode 9 (a second control electrode) is provided, which extends from the side where the first major surface 3a is located to the side where the bottom face 5a of the trench 5 is located. An end 9b of the FP electrode 9 on the bottom face side of the trench 5 is located between the bottom face 5a and an end 7a of the gate electrode 7 on the bottom face side. The FP electrode 9 faces the inner surface of the trench 5 through an FP insulating film 13. A portion 9a of the FP electrode 9 on the side where a source electrode 29 (a first major electrode) is located extends between the two gate electrodes 7.

The source electrode 29 is electrically connected to the p-type base region 15 and the n-type source region 17. For example, as shown in FIG. 1, the source electrode 29 is provided in such a way that the source electrode 29 contacts with the surface of the n-type source region 17 and the surface of a p⁺ contact region 19 provided on the bottom face of a contact trench 23 piercing through the n-type source region 17.

On the other hand, a drain electrode 27 (a second major electrode) is provided on the side where the second major surface 3b of the n-type drift layer 3 is located. For example, the drain electrode 27 is electrically connected to the n-type drift layer 3 through the n⁺ drain layer 2 containing an n-type impurity at a concentration higher than in the n-type drift layer 3.

At the depth position between an end 15a of the p-type base region 15 on the side where the second major surface 3b is located and an end 9b of the FP electrode 9 on the bottom face side of the trench 5, a first portion 21 is provided, which has an n-type carrier concentration lower than an n-type carrier concentration in the other portions of the n-type drift layer 3. Namely, the drift layer 3 has the first portion 21. The first portion 21 contains a p-type impurity at a concentration lower than the concentration of an n-type impurity contained in the n-type drift layer 3, for example, compensating an n-type impurity. Hence the first portion 21 becomes an n-type portion having a lower carrier concentration than the other portions of the n-type drift layer 3. The first portion 21 may be formed by reducing the amount of an n-type impurity doped therein or by adding a p-type impurity thereto, while epitaxially growing the n-type drift layer.

In this embodiment, an example will be described in which a p-type impurity is ion-implanted in the first portion 21 and the first portion 21 is turned into an n-type at a concentration lower than the concentrations of the other portions. As shown in FIG. 1, the first portion 21 is provided at the depth position of the end 7a of the gate electrode 7 on the bottom face side of the trench 5. For example, the first portion 21 is formed in such a way that the position of the concentration peak of a p-type impurity contained in the first portion 21 is at the same depth position of the end 7a of the gate electrode 7. Here, the term “same depth position” means the same depth position in a strict meaning as well as includes the meaning that one is located near the depth position.

The first portion 21 may be provided at the depth position between the end 7a of the gate electrode 7 and the end 9b of the FP electrode 9. Preferably, the first portion 21 is provided near the end 7a on the side where the second major surface 3b is located.

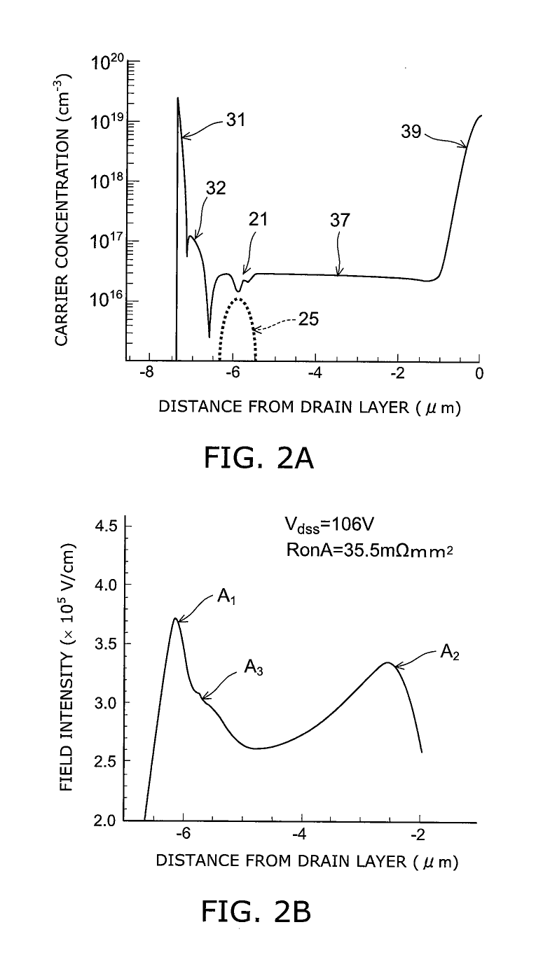

FIG. 2A and FIG. 2B are graphs illustrating the carrier concentration distribution and electric field distribution of the semiconductor device 100. In FIG. 2A, the carrier concentrations of the n-type drift layer 3, the p-type base region 15, and the n-type source region 17 are plotted on the vertical axis, and a distance from the n⁺ drain layer 2 is plotted on the horizontal axis. In FIG. 2B, the field intensity is plotted on the vertical axis, and a distance from the n⁺ drain layer 2 is potted on the horizontal axis.

FIG. 2A shows an electron concentration 31 of the n-type source region 17, a hole concentration 32 of the p-type base region 15, and an electron concentration 37 of the n-type drift layer 3. In the following, the electron concentration is referred to as the n-type carrier concentration, and the hole concentration is referred to as the p-type carrier concentration.

The boundary between the p-type base region 15 and the n-type drift layer 3, that is, the end of the p-type base region 15 on the side where the second major surface 3b is located is located at a position −6.6 μm apart from the n⁺ drain layer 2. The n-type carrier concentration of the n-type drift layer 3 is 2.3×10¹⁶ cm⁻³. The n-type carrier concentration is increased at an end 39 on the side where the n⁺ drain layer 2 is located. Such carrier concentration distribution is produced in which an n-type impurity is diffused from the n⁺ drain layer 2 to the n-type drift layer 3 while epitaxially growing the n-type drift layer 3 on the n⁺ drain layer 2.

In FIG. 2A, a broken line indicates the distribution of a p-type impurity 25 contained in the first portion 21. The p-type impurity 25 has a concentration peak at a position −5.8 μm apart from the n⁺ drain layer 2. In association with this peak, the n-type carrier concentration of the first portion 21 is the lowest at the peak position of the p-type impurity, and the concentration is lower than the concentrations of the other portions.

FIG. 2B shows electric field distribution in the n-type drift layer 3 at the breakdown voltage. This electric field distribution is obtained from simulation based on the carrier concentration distribution shown in FIG. 2A.

For example, two electric field concentrations, which are a breakdown point, are generated as corresponding to the depth position of the end 7a of the gate electrode 7 and the depth position of the end 9b of the FP electrode 9 on the bottom face side of the trench 5. An electric field peak A₁ corresponds to the electric field concentration at the depth position of the end 7a of the gate electrode 7, and an electric field peak A₂ corresponds to the electric field concentration at the depth position of the end 9b of the FP electrode 9. In the semiconductor device 100, a drain-source breakdown voltage V_{dss} is estimated as 106 V, and the ON resistance R_{onA} is estimated as 35.5 mΩmm².

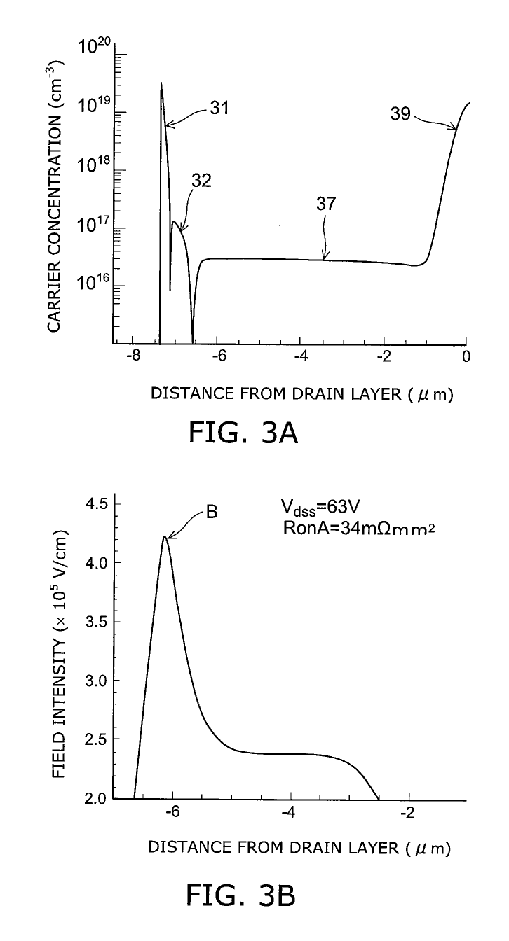

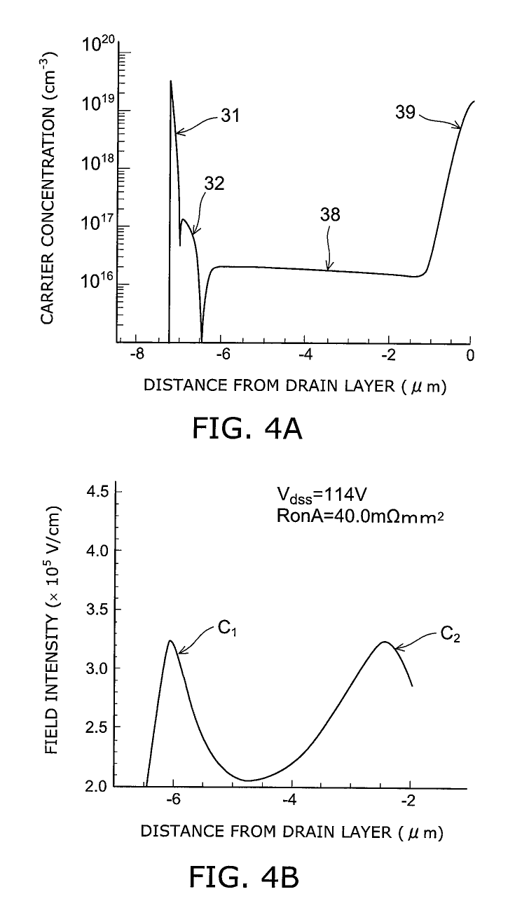

FIG. 3A and FIG. 3B are graphs illustrating the carrier concentration distribution and electric field distribution of a semiconductor device 110 (not shown) according to a comparative example. FIG. 4A and FIG. 4B are graphs illustrating the carrier concentration distribution and electric field distribution of a semiconductor device 120 (not shown) according to another comparative example. The semiconductor devices 110 and 120 are provided without the first portion 21, and carrier concentration distributions in both devices do not include the p-type impurity 25 as shown in FIG. 3A and FIG. 4A. The other components are the same as in the semiconductor device 100 shown in FIG. 1.

The n-type carrier concentration of an n-type drift layer 3 of the semiconductor device 110 is 2.3×10¹⁶ cm⁻³, which is the same as the n-type carrier concentration of the semiconductor device 100. On the other hand, the n-type carrier concentration of an n-type drift layer 3 of the semiconductor device 120 is 1.4×10¹⁶ cm⁻³.

As shown in FIG. 3B, in the semiconductor device 110, an electric field is concentrated at a position slightly closer to the pn junction between a p-type base region 15 and the n-type drift layer 3 on the side where an n⁺ drain layer 2 is located (a position −6.2 μm apart from the n⁺ drain layer 2), and a single electric field peak B is generated. This position is the same as the position at which the electric field peak A₁ shown in FIG. 2B is located, and the field intensity of the electric field peak B is higher than the field intensity of the electric field peak A₁. The breakdown voltage V_{dss} of the semiconductor device 110 is 63 V, and the ON resistance R_{onA} is estimated as 34 mΩmm².

In the comparison of the semiconductor device 100 with the semiconductor device 110, the breakdown voltage is higher in the semiconductor device 100, and the ON resistance is slightly smaller in the semiconductor device 110. Since the difference between the semiconductor devices 100 and 110 is only the presence or absence of the first portion 21, it is revealed that the first portion 21 improves the breakdown voltage. Namely, providing the first portion 21 causes an electric field A₃ to increase in the portion where the first portion 21 is provided and relaxes the electric field concentration near pn junction. The electric field peak B shown in FIG. 3B is reduced to the electric field peak A₁ shown in FIG. 2B. Another concentration of the electric field is further generated on the side where the n⁺ drain layer 2 is located, raising the electric field peak A₂. As a result, the breakdown voltage, which is the integral of the electric field distribution, is increased. On the other hand, although providing the first portion 21 increases the ON resistance due to a low carrier concentration thereof, the amount of an increase in the ON resistance is small, and the effect of increasing the breakdown voltage is advantageous.

On the other hand, as shown in FIG. 4B, in the electric field distribution of the semiconductor device 120, an electric field peak C₁ on the pn junction side and an electric field peak C₂ on the side where the n⁺ drain layer 2 is located are generated. The electric field peak C₁ and the electric field peak C₂ have the same intensity, and the field intensities of the electric field peak C₁ and the electric field peak C₂ are lower than the field intensity of the electric field peak A₁ in the semiconductor device 100. The breakdown voltage V_{dss} of the semiconductor device 120 is 114 V, which is higher than the breakdown voltage V_{dss} of the semiconductor device 100. However, since the n-type carrier concentration of the n-type drift layer 3 is low, the ON resistance R_{onA} is 40 mΩmm², which is about 10% higher than the ON resistance R_{onA} of the semiconductor device 100.

The advantage of this embodiment can be explained as bellow, when the relationships between the aforementioned semiconductor devices 100, 110, and 120 are seen from a different viewpoint. For example, when the n-type carrier concentration of the n-type drift layer 3 is simply increased in order to reduce the ON resistance of the semiconductor device 120, the breakdown voltage is reduced as in the semiconductor device 110. Therefore, the first portion 21 is provided in the n-type drift layer 3, in order to increase the breakdown voltage. Thus, it becomes possible to implement the semiconductor device 100 combining a high breakdown voltage and a low ON resistance.

In the semiconductor device 100, the degree of an increase in the breakdown voltage is changed depending on a position at which the first portion 21 is provided and the amount of a p-type impurity contained in that position. The position of the first portion 21 and the amount of the p-type impurity are designed appropriately, so that it is possible to implement a desired breakdown voltage and ON resistance.

As discussed above, the electric field concentration on the pn junction side is generated at the depth position of the end 7a of the gate electrode 7 on the bottom face side of the trench 5. In order to relax this electric field concentration, desirably, the first portion 21 is provided near the end 7a of the gate electrode 7 on the side where the n⁺ drain layer 2 is located as shown in this embodiment.

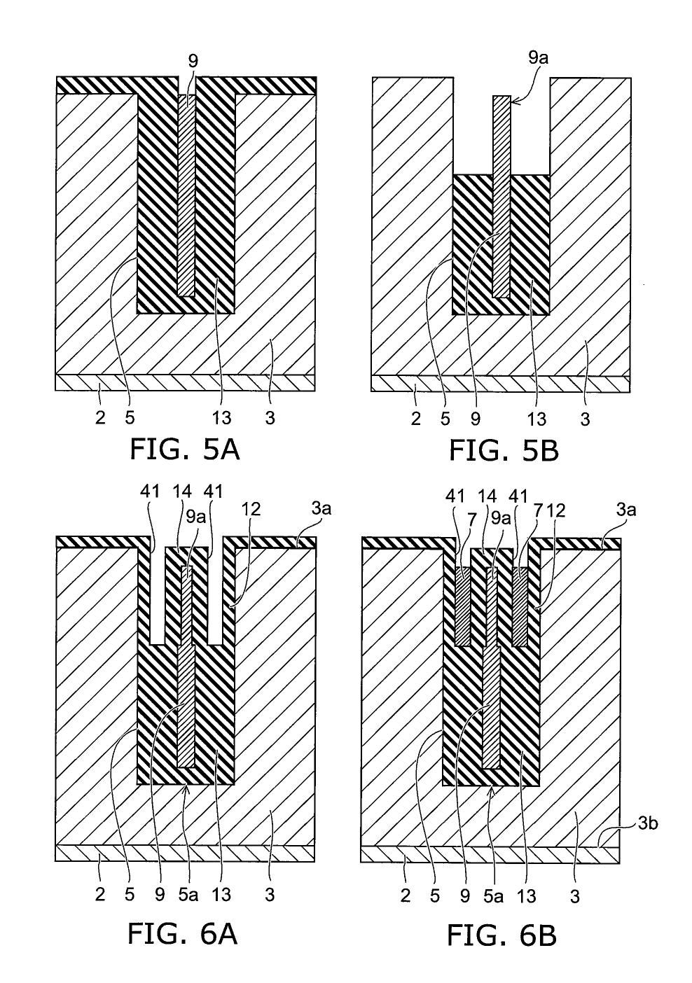

Next, the manufacture process steps of the semiconductor device 100 will be described with reference to FIG. 5A to FIG. 9B. FIG. 5A to FIG. 9B are schematic views illustrating a partial cross section of a wafer in the individual process steps.

First, as shown in FIG. 5A, the FP electrode 9 is formed in the trench 5 provided in the n-type drift layer 3. For example, the n-type drift layer 3 is an n-type silicon layer epitaxially grown on a silicon substrate. The silicon substrate is an n⁺ substrate containing a high-concentration n-type impurity, also serving as the n⁺ drain layer 2. The trench 5 is formed by selectively dry-etching the n-type drift layer 3 using a silicon oxide film (a SiO₂ film) as a mask, for example. Subsequently, the inner surface of the trench 5 is thermally oxidized, and the FP insulating film 13 is formed. An n-type polysilicon layer is formed on the surface of the wafer to burry the inside of the trench 5. The polysilicon layer on the surface of the wafer is etch-backed leaving the n-type polysilicon in the trench 5, which serves as the FP electrode 9 in.

Subsequently, as shown in FIG. 5B, the FP insulating film 13 is etch-backed from the surface of the wafer, and a part of the FP electrode 9 is exposed.

Subsequently, as shown in FIG. 6A, the inner surface in the upper part of the trench 5 is thermally oxidized, and the gate insulating film 12 is formed. At the same time, the surface of the exposed portion 9a of the FP electrode 9 is also thermally oxidized, and the insulating film 14 is formed therefrom. The insulating film 14 insulates the gate electrode 7 from the FP electrode 9.

Subsequently, an n-type polysilicon layer is formed on the surface of the wafer, which buries a space between the gate insulating film 12 and the insulating film 14. The n-type polysilicon layer formed on the surface of the wafer is etch-backed leaving the n-type polysilicon which serves as the gate electrode 7.

Thus, as shown in FIG. 6B, two gate electrodes 7 are formed, facing the sidewall of the trench 5 through the gate insulating film 12. The FP electrode 9 extending deeper than the gate electrode 7 is formed from the side where the first major surface 3a of the n-type drift layer 3 is located toward the bottom face 5a of the trench 5.

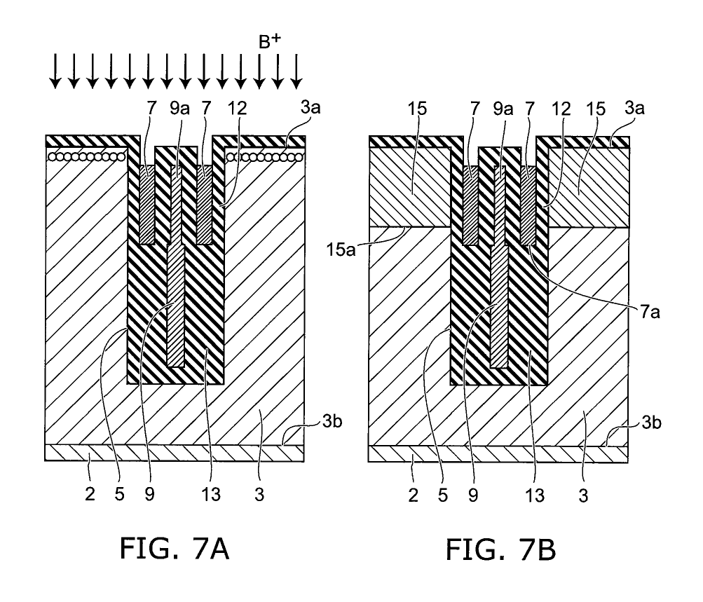

Subsequently, as shown in FIG. 7A, boron (B), which is a p-type impurity, for example, is ion-implanted from the first major surface 3a side. Subsequently, the ion-implanted p-type impurity is activated by applying heat treatment, and further diffused.

Thus, the p-type base region 15 is formed as shown in FIG. 7B. Heat treatment is carried out at a temperature of 1,000° C. for about ten minutes, for example. As shown in FIG. 7B, the end 15a of the p-type base region 15 on the side where the second major surface 3b is located is formed in such a way that the end 15a is shallower than the end 7a of the gate electrode 7 on the bottom face side of the trench 5.

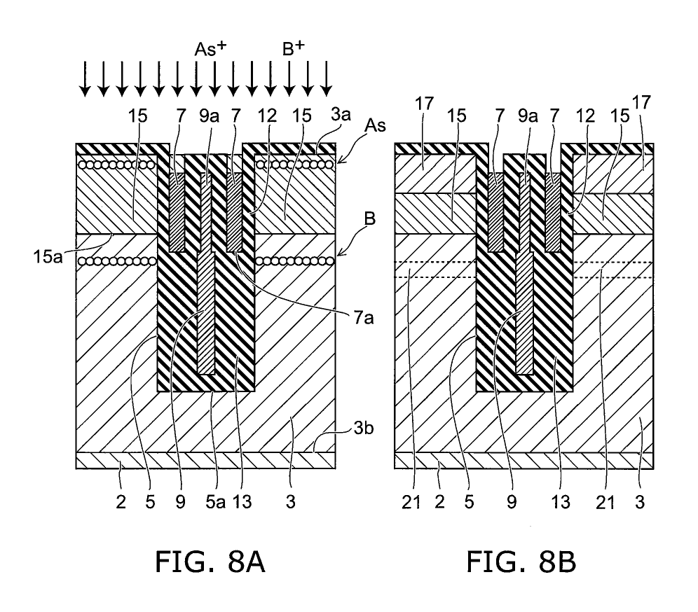

Subsequently, as shown in FIG. 8A, arsenic (As), which is an n-type impurity, and boron (B), which is a p-type impurity, for example, are ion-implanted from the first major surface 3a side. The implantation energy of arsenic is 30 keV, for example. On the other hand, the implantation energy of boron is set in such a way that boron is implanted at the same depth position of the end 7a of the gate electrode 7 on the bottom face side of the trench 5, for example. The amount of boron dosed is 6×10¹¹ cm⁻², for example, which is an amount that the n-type drift layer 3 is not inverted into the p-type. Thus, arsenic is ion-implanted near the surface of the p-type base region 15 on the side where the first major surface 3a is located, and boron is ion-implanted at a position deeper than the end 15a of the p-type base region 15 on the side where the second major surface 3b is located.

Subsequently, the p-type impurity B and the n-type impurity As, which are ion-implanted, are activated by applying heat treatment. Then, a temperature for the heat treatment is set to 800° C., for example, whereby the diffusion of boron is suppressed. Thus, as shown in FIG. 8B, the n-type source region 17 is formed on the surface of the p-type base region 15, and the first portion 21 is formed at a position deeper than the end 15a of the p-type base region 15 (the same depth position as the depth of the end 7a of the gate electrode 7). Thereby, the trench gate structure is formed in which the gate electrode 7 faces the p-type base region 15 and the n-type source region 17 through the gate insulating film 12.

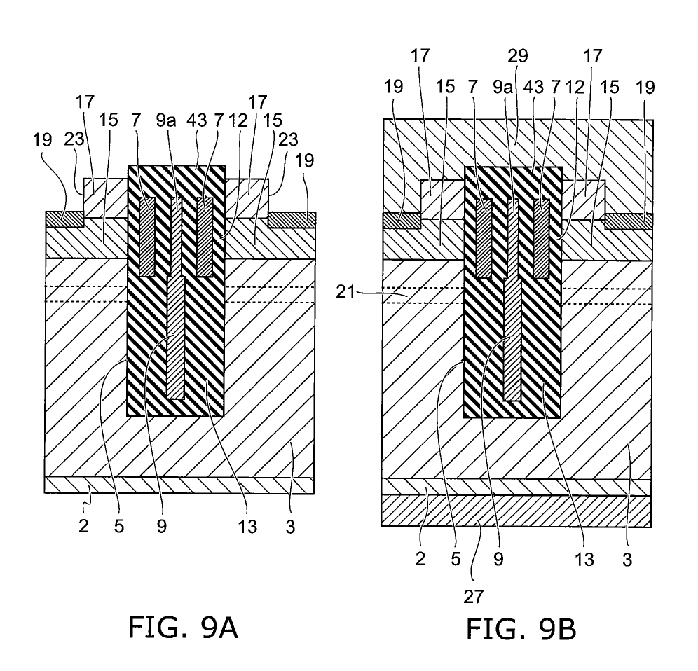

Subsequently, as shown in FIG. 9A, an interlayer insulating film 43 is formed on the trench 5, and the insulating film is removed on the other portions. The contact trench 23 reaching the p-type base region 15 from the surface of the n-type source region 17 is formed, and the p⁺ contact region 19 is formed on the bottom face of the contact trench 23.

Subsequently, as shown in FIG. 9B, the source electrode 29 is formed, which contacts with the n-type source region 17 and the p⁺ contact region 19 and covers the interlayer insulating film 43. On the other hand, the drain electrode 27 is formed on the back surface of the n⁺ drain layer 2 (the surface on the opposite side of the n-type drift layer 3). Thereafter, the semiconductor device 100 is completed cutting individual chips out of the wafer, and assembling in a predetermined package.

As described above, in this embodiment, the first portion 21 having an n-type carrier concentration lower than an n-type carrier concentration in the other portions is provided in the n-type drift layer 3, so that the electric field concentration near the end 7a of the gate electrode 7 is relaxed, and the breakdown voltage is increased. Thus, it is possible to increase the n-type carrier concentration in the n-type drift layer and to reduce the ON resistance.

This embodiment can be easily implemented by additionally providing a process step of ion-implanting the p-type impurity to the n-type drift layer 3. Therefore, it is possible to implement a semiconductor device having a high breakdown voltage and a low ON resistance without increase in manufacturing costs.

In the semiconductor device 100, a breakdown voltage of 100 V or more can be reliably secured, and the ON resistance can be reduced by 10%. Thus, it is possible to scale down the chip size by 10%, for example, and to reduce manufacturing costs.

### Second Embodiment

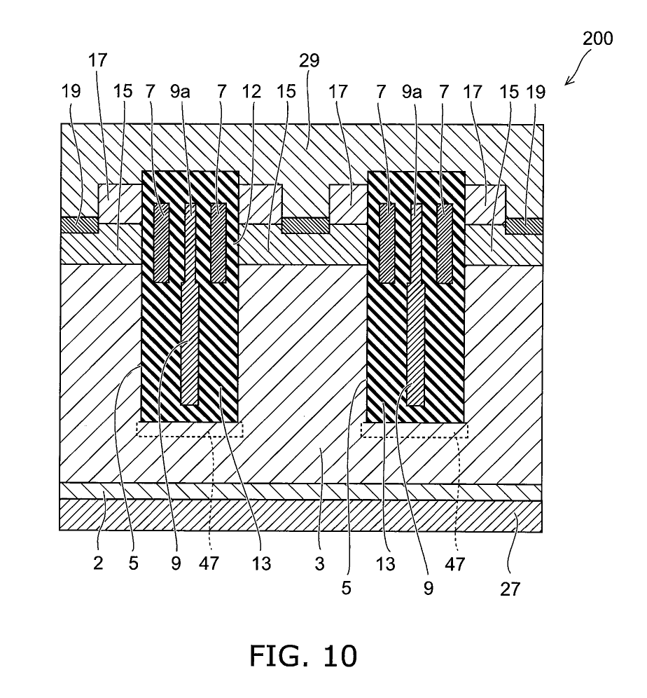

FIG. 10 is a cross-sectional view schematically illustrating a semiconductor device 200 according to a second embodiment. The semiconductor device 200 is different from the semiconductor device 100 shown in FIG. 1 in that a second portion 47 surrounding the bottom of a trench 5 is provided in an n-type drift layer 3, instead of the first portion 21. Namely, the drift layer, 3 has the second portion 47. The n-type carrier concentration is set to the second portion 47, which is lower than the n-type carrier concentration in the other portions of the n-type drift layer 3.

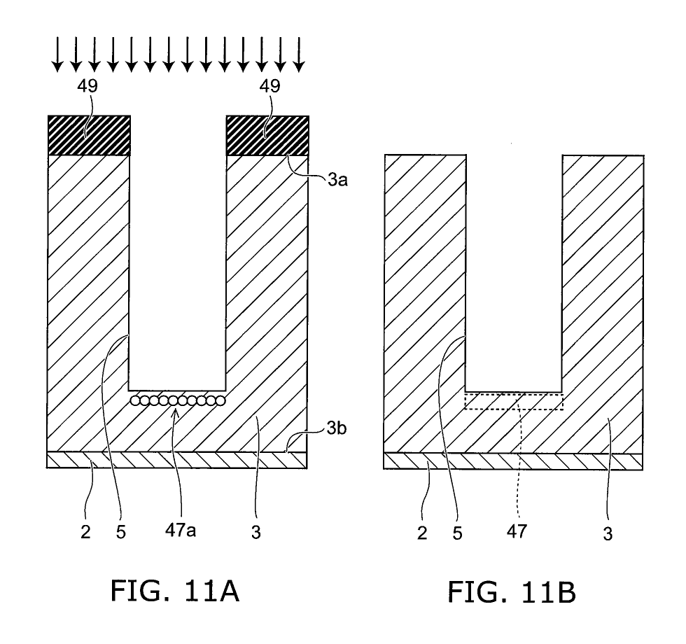

As shown in FIG. 11A, a hard mask 49 is provided on a first major surface 3a of the n-type drift layer 3, and the trench 5 is formed in the direction of a second major surface 3b using dry etching, for example. Subsequently, boron (B), for example, is ion-implanted using the hard mask 49 as an implantation mask, and an implanted layer 47a is formed on the bottom of the trench 5.

The hard mask 49 is a SiO₂ film, for example, and patterned in the plane shape of the trench 5. The implantation energy of boron is 30 keV, for example, and the amount dosed is kept lower than an amount that inverts the n-type drift layer 3 into the p-type.

Subsequently, the process steps in FIG. 5A to FIG. 9B are performed, so that the semiconductor device 200 shown in FIG. 10 is completed. However, in this embodiment, the ion implantation of a p-type impurity is not performed in the first portion 21.

The implanted layer 47a formed on the bottom of the trench 5 is activated to be the second portion 47 by heat treatment in the subsequent process steps. For example, such a process may be performed, where heat treatment is carried out subsequently after the boron implantation as shown in FIG. 11B. Boron contained in the second portion 47 is diffused and redistributed by heat treatment while forming the p-type base region 15. Thus, the peak concentration of boron in the second portion 47 tends to be lower than t in the first portion 21. Therefore, it is possible to increase the amount of boron dosed, for example, which is implanted on the bottom of the trench 5, more than the amount of boron dosed, which forms the first portion 21. More specifically, it is possible that the amount dosed in the second portion 47 is 8×10¹² cm⁻², for example, which is one digit greater than the amount dosed in the first portion 21.

According to this embodiment, the second portion 47 surrounding the bottom of the trench 5 is provided, so that the electric field concentration on the pn junction side is relaxed, and the electric field peak B (see FIG. 3B) is reduced. Thus, it is possible to increase field intensity by depleting the bottom of the trench 5, and make the breakdown voltage higher. As a result, by increasing the n-type carrier concentration of the n-type drift layer 3, it becomes possible to implement a semiconductor device having a high breakdown voltage and a low ON resistance. This embodiment can also be easily implemented by additionally providing the process step of ion implantation to the bottom of the trench 5.

### Third Embodiment

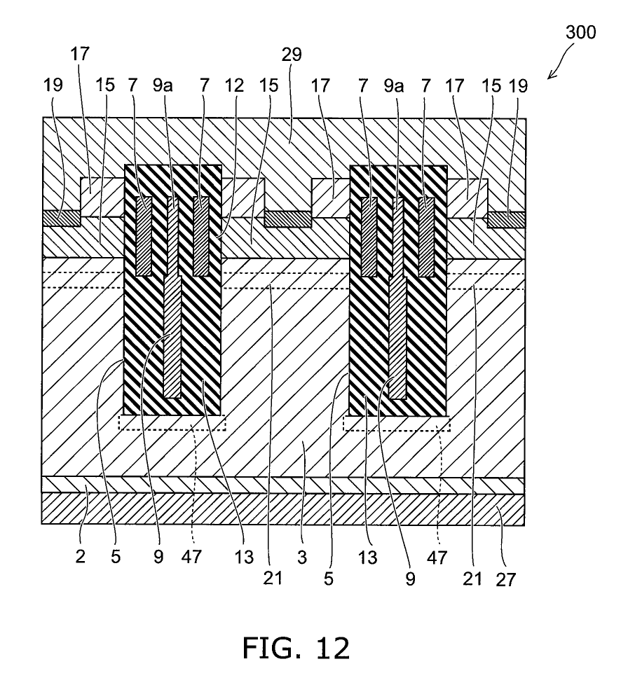

FIG. 12 is a cross-sectional view schematically illustrating a semiconductor device 300 according to a third embodiment. The semiconductor device 300 is different from the semiconductor devices 100 and 200 in that both of the first portion 21 and the second portion 47 are provided.

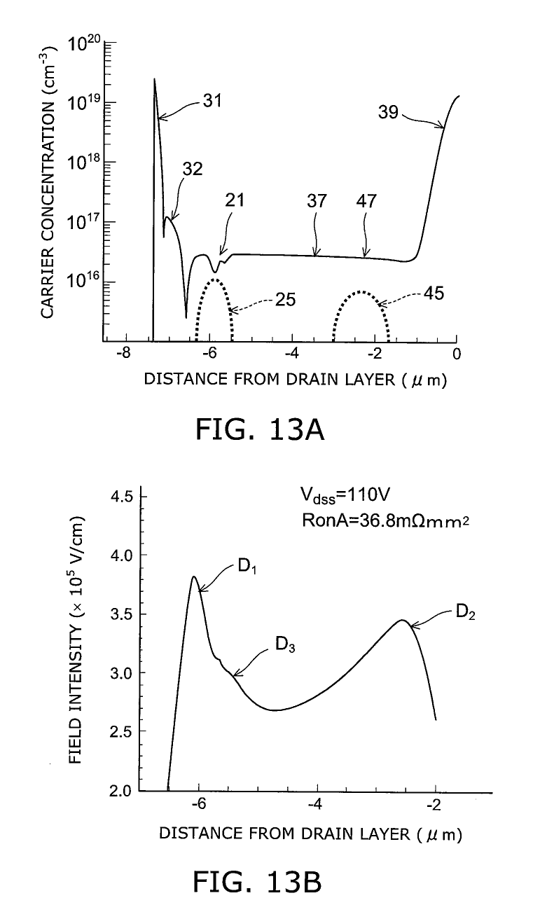

As shown in the carrier concentration distribution in FIG. 13A, the semiconductor device 300 includes a p-type impurity 25 near the depth position of an end 7a of a gate electrode 7, and includes a p-type impurity 45 on the bottom of a trench 5. An n-type carrier concentration 37 of an n-type drift layer 3 is 2.3×10¹⁶ cm⁻³, which is the same in the semiconductor device 100.

The electric field distribution shown in FIG. 13B has electric field peaks D₁ and D₂ corresponding to two electric field concentrations and a portion D₃ in which an electric field is increased as corresponding to the first portion 21. In this embodiment, in addition to the portion D₃ corresponding to the first portion 21, the second portion 47 provided on the bottom of the trench 5 increases the electric field peak D₂ on the side where an n⁺ drain layer 2 is located. Thus, the breakdown voltage V_{dss} is increased to 110 V. On the other hand, although the ON resistance R_{onA} becomes slightly higher as 36.8 mΩmm², the amount of an increase in the ON resistance R_{onA} is small. Therefore, it is possible to increase the n-type carrier concentration of the n-type drift layer 3 and to reduce the ON resistance while reliably securing a breakdown voltage equivalent to the breakdown voltage in the semiconductor device 100.

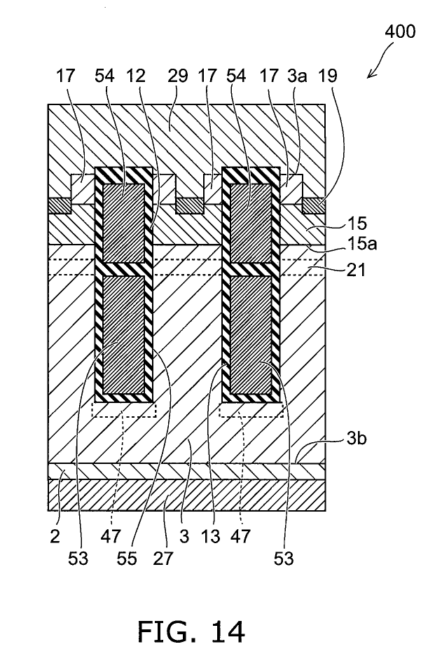

FIG. 14 is a cross-sectional view schematically illustrating a semiconductor device 400 according to a variation of this embodiment. In the semiconductor device 400, an FP electrode 53 is provided on the bottom face side of a trench 55, and a gate electrode 54 is provided on the side where a first major surface 3a is located. Namely, this variation is different from the semiconductor device 300, having the FP electrode 9 extending between the two gate electrodes 7, in that the gate electrode 54 is disposed above the FP electrode 53 as shown in FIG. 14.

Also in the semiconductor device 400, the first portion 21 is provided at the depth position of the end of the gate electrode 54 on the bottom face side of the trench 55, and the second portion 47 surrounding the bottom of the trench 55 is provided. This structure is suitable in the case where the width of the trench 55 is narrow, for example, and it is possible to easily implement a semiconductor device having a high breakdown voltage and a low ON resistance.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a semiconductor layer of a first conductive type;
a first semiconductor region of a second conductive type provided on the semiconductor layer;
a second semiconductor region of a first conductive type selectively provided on a surface of the first semiconductor region;
a first control electrode facing the first semiconductor region and the second semiconductor region through an insulating film in a trench, the trench piercing through the first semiconductor region and reaching the semiconductor layer, the trench having a bottom face at a position deeper than the first semiconductor region;
a second control electrode extending to the bottom face of the trench and having a portion located between the bottom face and the first control electrode;
a first major electrode electrically connected to the first semiconductor region and the second semiconductor region; and
a second major electrode electrically connected to the semiconductor layer,
the semiconductor layer including a first portion provided at a depth position between an end of the first semiconductor region and an end of the second control electrode on the bottom face side, a first conductive type carrier concentration in the first portion being lower than a first conductive type carrier concentration in other portions of the semiconductor layer.

2. The device according to claim 1, wherein the first portion contains a second conductive type impurity at a concentration lower than a concentration of a first conductive type impurity contained in the semiconductor layer.

3. The device according to claim 2, wherein the semiconductor is an n-type silicon layer; and the first portion contains boron that is a p-type impurity.

4. The device according to claim 1, wherein an end of the first control electrode on the bottom face side of the trench is provided at a position deeper than the first semiconductor region; and
the second conductive type impurity contained in the first portion has a concentration peak at the same depth position as the end of the first control electrode on the bottom face side.

5. The device according to claim 1, wherein an end of the first control electrode on the bottom face side of the trench is provided at a position deeper than the first semiconductor region; and
the first portion is provided between the end of the first control electrode on the bottom face side and the end of the second control electrode on the bottom face side.

6. The device according to claim 1, wherein the semiconductor layer further includes a second portion surrounding a bottom of the trench, the second portion having a first conductive type carrier concentration lower than a first conductive type carrier concentration in other portions of the semiconductor layer except the first portion.

7. The device according to claim 6, wherein the second portion contains a second conductive type impurity at a concentration lower than a concentration of a first conductive type impurity contained in the semiconductor layer.

8. The device according to claim 7, wherein the semiconductor layer is an n-type silicon layer; and the second portion contains boron that is a p-type impurity.

9. The device according to claim 1, wherein the first portion has a first conductive type impurity concentration lower than a first conductive type impurity concentration in other portions of the semiconductor layer.

10. The device according to claim 1, wherein a pair of the first control electrodes is provided in the trench; and the second control electrode extends between the pair of the first control electrodes.

11. The device according to claim 1, wherein the second control electrode is provided between the first control electrode and the bottom face of the trench.

12. The device according to claim 1, further comprising:
a third semiconductor region of a second conductive type selectively provided on the surface of the first semiconductor region,
the first major electrode electrically connected to the first semiconductor region through the third semiconductor region.

13. The device according to claim 1, further comprising:
a layer contacting with a surface on an opposite side of the semiconductor layer from the first semiconductor region, and containing a first conductive type impurity at a concentration higher than the semiconductor layer,
the second major electrode electrically connected to the semiconductor layer via the layer.

14. A semiconductor device comprising:
a semiconductor layer of a first conductive type;
a first semiconductor region of a second conductive type provided on the semiconductor layer;
a second semiconductor region of a first conductive type selectively provided on a surface of the first semiconductor region;
a first control electrode facing the first semiconductor region and the second semiconductor region through an insulating film in a trench, the trench piercing through the first semiconductor region and reaching the semiconductor layer, the trench having a bottom face at a position deeper than the first semiconductor region;
a second control electrode extending to the bottom face of the trench and having a portion between the bottom face and the first control electrode;
a first major electrode electrically connected to the first semiconductor region and the second semiconductor region; and
a second major electrode electrically connected to the semiconductor layer,
the semiconductor layer including a second portion surrounding a bottom of the trench, the second portion containing a second conductive type impurity at a concentration lower than a concentration of a first conductive type impurity contained in the semiconductor layer, the second portion having a first conductive type carrier concentration lower than a first conductive type carrier concentration of other portions in the semiconductor layer.

15. A method for manufacturing a semiconductor device comprising:
forming, in a trench provided on a first major surface of a semiconductor layer of a first conductive type, a first control electrode facing a sidewall of the trench through an insulating film and a second control electrode extending deeper than the first control electrode from the first major surface side to a bottom face of the trench;
ion-implanting a second conductive type impurity in the semiconductor layer from the first major surface side and forming a first semiconductor region of a second conductive type by applying heat treatment;
ion-implanting a second conductive type impurity from the first major surface side at a concentration lower than a concentration of a first conductive type impurity contained in the semiconductor at a position deeper than the first semiconductor region;
ion-implanting a first conductive type impurity in the first semiconductor region from the first major surface side; and
simultaneously applying heat treatment for activating the second conductive type impurity ion-implanted at the position deeper than the first semiconductor region and the first conductive type impurity ion-implanted in the first semiconductor region for activation.

16. The method according to claim 15, wherein a temperature of heat treatment activating the impurity ion-implanted at the position deeper than the first semiconductor region is lower than a temperature of heat treatment while forming the first semiconductor region.

17. The method according to claim 15, wherein the semiconductor layer is an n-type silicon layer; the first conductive type impurity is arsenic; and the second conductive type impurity is boron.

18. The method according to claim 15, further comprising:
ion-implanting, on a bottom of the trench, a second conductive type impurity at a concentration lower than a concentration of a first conductive type impurity contained in the semiconductor.

19. The method according to claim 15, wherein the second conductive type impurity ion-implanted at the position deeper than the first semiconductor region is located at a depth position of an end of the first control electrode on the bottom face side of the trench.

20. The method according to claim 15, wherein the second conductive type impurity ion-implanted at the position deeper than the first semiconductor region is located at a depth position between an end of the first control electrode on the bottom face side of the trench and an end of the second control electrode on the bottom face side.
